(19) United States
(12) Patent Application Publication
(10) Pub. No.: US 2010/0287426 A1
(43) Pub. Date: Nov. 11, 2010

(54) MEMORY CHECKING SYSTEM AND METHOD

(75) Inventors: Tomoaki KANAI, Kawasaki (JP); Hiroyuki KII, Kawasaki (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kawasaki (JP)

(21) Appl. No.: 12/774,864

(22) Filed: May 6, 2010

(30) Foreign Application Priority Data
May 11, 2009 (JP) 2009-114278

(51) Int. Cl. G11C 29/04; G06F 11/22

(52) U.S. Cl. 714/718; 714/E11.145; 710/22

(57) ABSTRACT

A memory checking system according to the present invention includes a memory that stores a data to be checked, a check circuit that checks the memory by using the data to be checked and a reference check code of the data to be checked, and a transfer circuit that transfers the data to be checked from the memory to the check circuit based on a transfer setting information of the data to be checked. The transfer setting information is registered in advance in the memory.

### INCORPORATION BY REFERENCE

This application is based upon and claims the benefit of priority from Japanese patent application No. 2009-114278, filed on May 11, 2009, the disclosure of which is incorporated herein in its entirety by reference.

### BACKGROUND

1. Field of the Invention

The present invention relates to a memory checking system and method. In particular, the present invention relates to a memory checking system and method for a memory storing data to be checked.

2. Description of Related Art

A microcomputer is usually equipped with a data memory, which is a storage device to store given data used as initial values for an operation. Such a microcomputer reads data stored in the data memory at the time of startup, and starts a predetermined operation. There is a possibility that data in the data memory could be lost when an error such as aged deterioration occurs. In this case, a microcomputer could not read correct data from the data memory, and thereby could not operate properly. Therefore, it is common for a microcomputer to perform an error detection processing by a startup routine when the microcomputer reads data at the time of startup. Then, the microcomputer starts a normal operation when the microcomputer does not detect any error in the error detection processing.

Japanese Unexamined Patent Application Publication No. 2001-344992 discloses a technology related to a semiconductor integrated circuit and a checking method for protecting confidentiality of data stored in a ROM (Read Only Memory) and for enabling the execution of a ROM test for a semiconductor integrated circuit equipped with the embedded ROM. The semiconductor integrated circuit equipped with a ROM according to Japanese Unexamined Patent Application Publication No. 2001-344992 stores confidential data. In addition, the ROM also stores confidential CRC (Cyclic Redundancy Check) data for data check. Further, a checking arithmetic circuit carries out an operation for generating the confidential CRC data on confidential information data read from the ROM. Further, a comparison circuit compares a result of the operation of the checking arithmetic circuit with the confidential information data read from the ROM.

### SUMMARY

The present inventor has found a problem that data transfer processing for performing the error detection processing of the data memory storing data requires a long time in Japanese Unexamined Patent Application Publication No. 2001-344992. This is because the semiconductor integrated circuit according to Japanese Unexamined Patent Application Publication No. 2001-344992 controls the data transfer processing for generating the confidential CRC data from the data memory by software. The controlling by software means, for example, that a CPU (Central Processing Unit) embedded in a semiconductor integrated circuit reads a program, on which data transfer processing is programmed, and executes the data transfer processing.

A first exemplary aspect of the present invention is a memory checking system including: a memory that stores data to be checked; a check circuit that checks the memory by using the data to be checked and a reference check code of the data to be checked; and a transfer circuit that transfers the data to be checked from the memory to the check circuit based on a transfer setting information of the data to be checked, the transfer setting information being registered in advance.

A second exemplary aspect of the present invention is a memory checking method for checking a memory storing data to be checked by using a transfer circuit and a check circuit. The method includes: reading, by the transfer circuit, the data to be checked from the memory based on a transfer setting information registered in advance in the memory; transferring, by the transfer circuit, the data to be checked read from the memory to the check circuit; checking, by the check circuit, the memory by using the data to be checked and a reference check code of the data to be checked.

In the a memory checking system and method according to the first and second exemplary aspects of the present invention, the transfer circuit operates, based on a transfer setting information registered in advance in the memory. Further it is possible to perform a data transfer in a short time compared with the controlling by software, because the data to be checked is transferred by the transfer circuit.

A third exemplary aspect of the present invention is a memory checking system including: a memory that stores a first data to be checked in a first area and a second data to be checked in a second area; a check circuit that checks the memory by using the first data, the second data, a first reference check code corresponding to the first data, and a second reference check code corresponding to the second data; a first transfer circuit that transfers the first data from the memory to the check circuit based on a first transfer setting information registered in advance in the memory, the first setting information specifying the first area; a second transfer circuit that transfers the second data from the memory to the check circuit based on a second transfer setting information registered in advance in the memory in parallel with the first transfer circuit, the second transfer setting information specifying the second area.

In the a memory checking system according to the third exemplary aspect of the present invention, it is possible to perform a data transfer in a short time compared with the controlling by software, because the data transfers of the first data and the second data can be performed in parallel in the first transfer circuit and the second transfer circuit.

According to an exemplary embodiment of the present invention, it is possible to provide a memory checking system and method capable of starting an error detection processing of a memory quickly.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a block diagram showing a configuration of a memory checking system according to a first exemplary embodiment of the present invention;

FIG. 2 is a flowchart showing a processing of a memory checking method according to a first exemplary embodiment of the present invention;

FIG. 3 is a block diagram showing a configuration of a memory checking system according to a second exemplary embodiment of the present invention;

FIG. 4 is a flowchart showing a processing of a memory checking method according to a second exemplary embodiment of the present invention;

FIG. 5 is a block diagram showing a configuration of a memory checking system according to a forth exemplary embodiment of the present invention; and

FIG. 6 is a flowchart showing a processing of a memory checking method according to a forth exemplary embodiment of the present invention.

### DETAILED DESCRIPTION OF THE EXEMPLARY EMBODIMENTS

Hereinafter, specific embodiments to which the present invention is applied will be described in detail with reference to the accompanying drawings. In the drawings, the same components are denoted by the same reference symbols, and redundant explanation thereof is omitted as appropriate to clarify the explanation.

### First Exemplary Embodiment

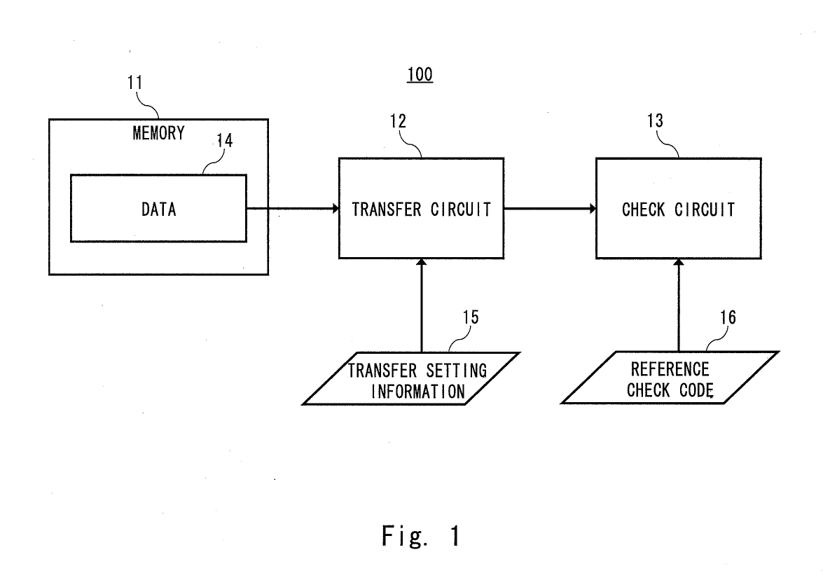

FIG. 1 is a block diagram showing a configuration of a memory checking system 100 according to a first exemplary embodiment of the present invention. The memory checking system 100 includes a memory 11, a transfer circuit 12, and a check circuit 13. The memory checking system 100 performs a test on the memory 11. For example, the memory checking system 100 performs an error detection processing for detecting whether or not an error occurs due to aged deterioration or the like in the memory 11. The memory checking system 100 outputs a message indicating that an error occurs as an error signal or the like when it detects an error. For example, the memory checking system 100 may be an embedded system such as a semiconductor integrated circuit or microcomputer equipped with the embedded memory 11. Alternatively, the memory checking system 100 may include a removable memory, and perform a test on any given removable memory connected to the system.

The memory 11 is a storage device to store data 14 to be checked. For example, the memory 11 may be a flash memory, a nonvolatile storage such as a ROM, or a volatile storage such as a RAM (Random Access Memory). The memory 11 stores at least the data 14 in advance.

The transfer circuit 12 transfers the data 14 from the memory 11 to the check circuit 13 based on a transfer setting information 15 of the data 14. The transfer setting information 15 is registered in advance in the memory 11. The transfer circuit 12 is a purpose-built electronic circuit for transferring data implemented by hardware. The transfer setting information 15 includes at least information about a transfer source and a transfer destination. For example, the transfer setting information 15 includes information indicating the memory 11 as the transfer source and the check circuit 13 as the transfer destination. The transfer setting information 15 includes at least an address in the memory 11 from which the reading starts (hereinafter called “reading start address”). That is, the transfer circuit 12 reads the data 14 from the memory 11 based on the transfer setting information 15. The transfer circuit 12 transfers the data 14 read from the memory 11 to the check circuit 13.

The check circuit 13 checks the memory 11 by using the data 14 and the reference check code 16 of the data 14. For example, the check circuit 13 generates a check code from the data 14 transferred from the transfer circuit 12. The check circuit 13 compares the generated check code with the reference check code 16 to determine the presence/absence of an error. When an error exists, the check circuit 13 determines that the memory 11 has the error. The reference check code 16 is code that is used for detecting an error and calculated from the data 14. The reference check code 16 is calculated in advance. Therefore, the check circuit 13 can detect an occurrence of an error such as lost data in the data 14 in the memory 11 when the check code, which is calculated from data 14 in the same manner as that of the reference check code 16, does not match with the reference check code 16.

Note that the transfer setting information 15 and the reference check code 16 may be stored in the memory 11 in advance. Alternately, the transfer setting information 15 and the reference check code 16 may be stored in other storage devices different from the memory 11 in advance. For example, the other storage device may be a storage device embedded in the memory checking system 100 or any storage device attachable/detachable to/from the memory checking system 100.

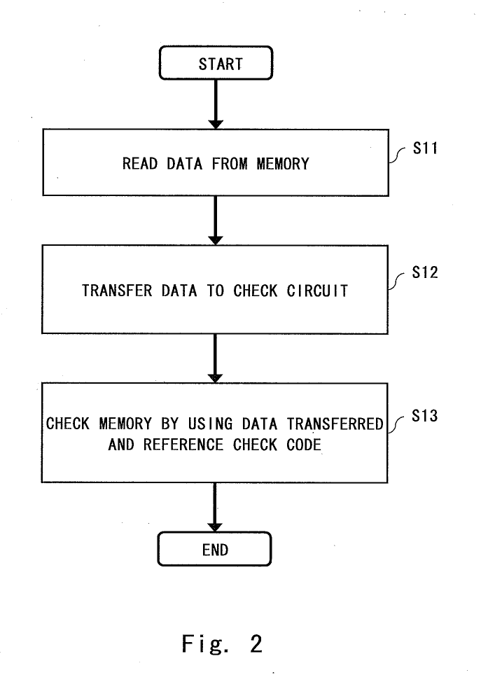

FIG. 2 is a flowchart showing processing of a memory checking method according to a first exemplary embodiment of the present invention. First, the transfer circuit 12 reads the data 14 from the memory 11 based on the transfer setting information 15 (S11). Next, the transfer circuit 12 transfers the data 14 read from the memory 11 to the check circuit 13 (S12). After that, the check circuit 13 checks the memory 11 by using the checked data 14 transferred from the transfer circuit 12 and a reference check code 16 of the data 14 (S13).

As described above, according to the first exemplary embodiment of the present invention, the memory checking system 100 realizes the data transfer processing for the error detection processing not by the controlling by software, but by the processing by hardware. Therefore, it is possible to complete the data transfer in a short time and to start an error detection processing of a memory 11 quickly.

### Second Exemplary Embodiment

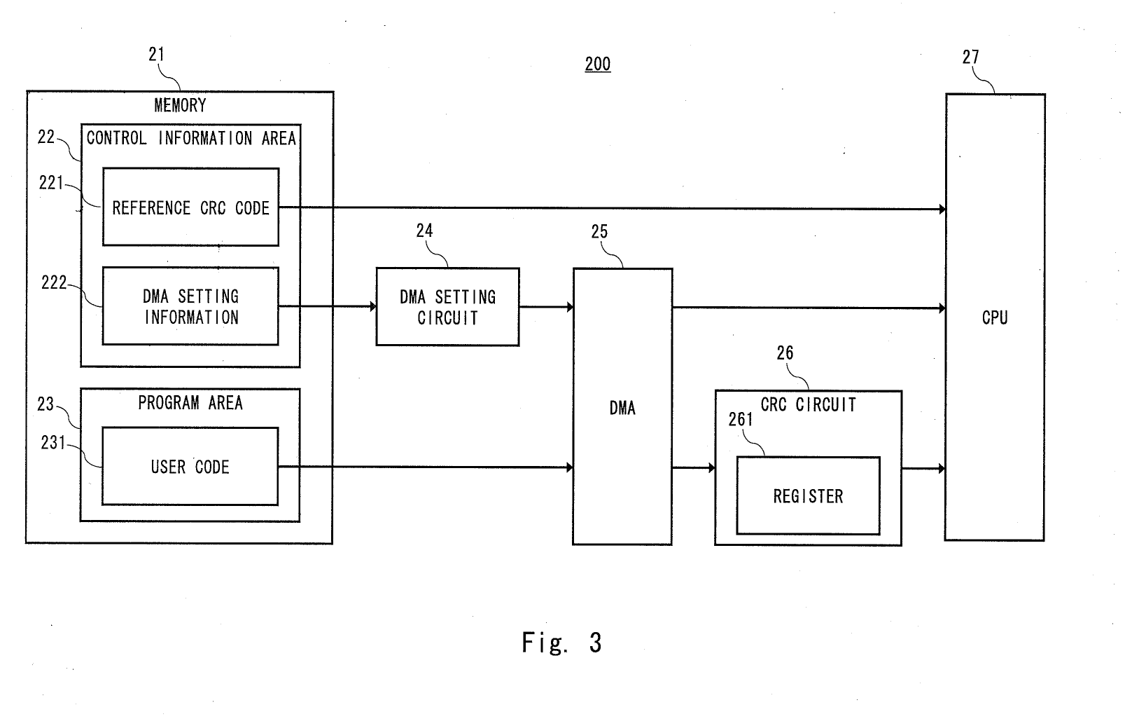

A second exemplary embodiment of the present invention is another embodiment in accordance with the first exemplary embodiment. FIG. 3 is a block diagram showing a configuration of a memory checking system according to a second exemplary embodiment of the present invention. A microcomputer 200 includes a memory 21, a DMA (Direct Memory Access) setting circuit 24, a DMA 25, a CRC circuit 26, and a CPU 27.

The memory 21 is a storage device similar to the memory 11. The memory 21 includes a control information area 22 and a program area 23. In the control information area 22, a reference CRC code 221 and a DMA setting information 222 are stored. In the program area 23, a user code 231 to be checked is stored. The reference CRC code 221 is code generated from the user code 231 in advance by a Cyclic Redundancy Check scheme. The DMA setting information 222 is transfer setting information for the data transfer processing by the DMA 25. For example, the DMA setting information 222 includes a transfer source and a transfer destination, and a reading start address in the memory 11 and the like. The DMA setting information 222 indicates the memory 12 as the transfer source and the CRC circuit 26 as the transfer destination. The user code 231 is data used in the operation of the microcomputer 200, e.g., initial values and the like. The reference CRC code 221, DMA setting information 222, and user code 231 are stored in the memory 21 in advance. As described above, the memory 21 includes the control information area 22 and the program area 23. Therefore, even if an error occurs in the control information area 22, the memory 21 can detect the error.

Note that the reference CRC code 221 may be stored in other storage devices different from the memory 21. Alternately, the DMA setting information 222 may be stored in other storage devices different from the memory 21. For example, the DMA setting information 222 may be stored in a storage device embedded in the DMA setting circuit 24.

The DMA setting circuit 24 outputs a transfer instruction to the DMA 25. In other words, the DMA setting circuit 24 is called a transfer instruction circuit. The DMA setting circuit 24 is a purpose-built electronic circuit for transferring data implemented by hardware. Further, The DMA setting circuit 24 reads the DMA setting information 222 from the memory 21 at the start-up of the microcomputer 200, and outputs a transfer instruction including the DMA setting information 222 to the DMA 25.

The DMA 25 is an embodiment of the transfer circuit 12. The DMA 25 is a DMA controller capable of directly transferring data between a memory and a memory or between a memory and an I/O device without using a group of instructions written in a machine language. The DMA 25 reads data stored at the reading start address and subsequent addresses, in the transfer source by a predetermined size at a time in the order determined based on the DMA setting information 222, and outputs the data read from the memory 21 to the transfer destination in that order. That is, the DMA 25 transfers the user code 231 from the memory 21, which is the transfer source, to the CRC circuit 26, which is the transfer destination, based on the DMA setting information 222 included in the transfer instruction from the DMA setting circuit 24. The DMA 25 outputs a transfer completion interrupt signal to the CPU 27 when the DMA 25 has finished transferring the user code 231 from the memory 21 to the CRC circuit 26.

The CRC circuit 26 generates a CRC code from input data in the order in which the input data is input by a Cyclic Redundancy Check scheme, and stores it in a register 261 to store the CRC code. The CRC circuit 26 is an electronic circuit for generating a CRC code implemented by hardware. However the CRC circuit 26 is not limited to such configurations. For example, the CRC circuit 26 may generate code by schemes other than the Cyclic Redundancy Check scheme such as an error check scheme.

The CPU 27 is a central processing unit for controlling the operation of the microcomputer 200. Note that the microcomputer 200 is an embedded system and includes a user program on which given processing is programmed (not shown) and a memory checking program for memory checking processing (not shown). The CPU 27 reads and executes the memory checking program, and the microcomputer 200 thereby performs the memory checking processing on the memory 21. Further the CPU 27 reads the user program and executes any given predetermined processing when it is determined that the memory has no error by the memory checking processing.

When the CPU 27 received a transfer completion interrupt signal from the DMA 25, the CPU 27 obtains a CRC code from the register 261, and obtains the reference CRC code 221 from the memory 21. Furthermore the CPU 27 compares the CRC code obtained from the register 261 with the reference CRC code 221, and outputs an error signal when they are different.

Note that the memory checking program may implement a logic corresponding to the CRC circuit 26. In this case, the combination of the CRC circuit 26 and the CPU 27 correspond to the check circuit 13.

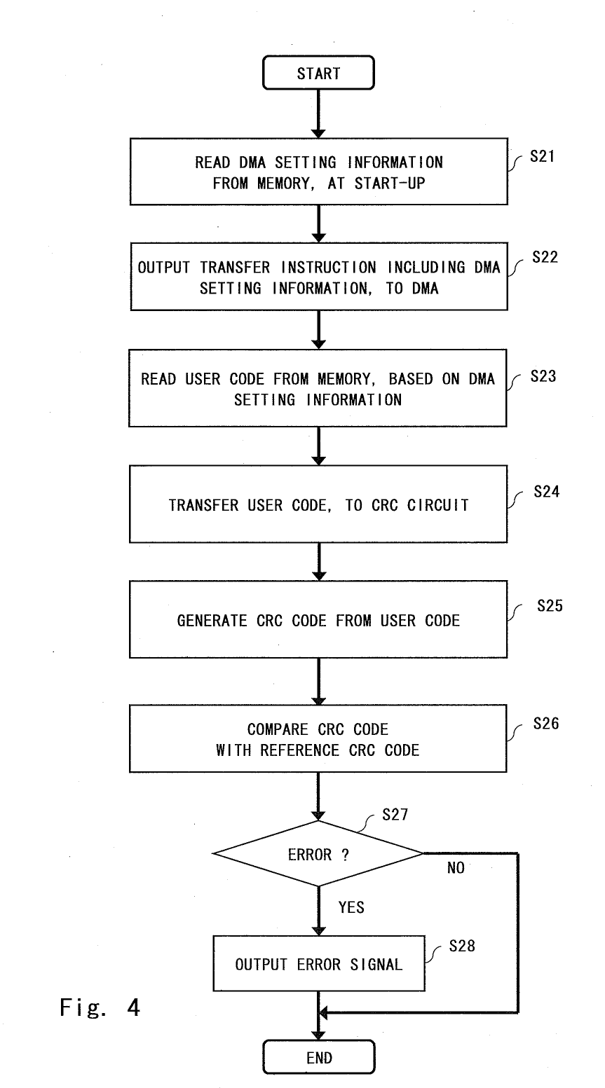

FIG. 4 is a flowchart showing processing of a memory checking method according to a second exemplary embodiment of the present invention. First, the DMA setting circuit 24 reads the DMA setting information 222 from the memory 21 at the start-up of the microcomputer 200, that is, at the time of the start of checking on the memory 21 (S21). Then, the CPU 27 may start reading the memory checking program. Next, the DMA setting circuit 24 outputs the transfer instruction including the DMA setting information 222 read from the memory 21 to the DMA 25 (S22).

Subsequently, the DMA 25 reads the user code 231 from the memory 21 based on the DMA setting information 222 (S23). Specifically, first, the DMA 25 receives the transfer instruction from the DMA setting circuit 24. Next, the DMA 25 extracts the DMA setting information 222 from the transfer instruction. Further, since the transfer source included in the DMA setting information 222 is the memory 21, the DMA 25 connects to the memory 21. In addition, the DMA 25 refers to the reading start address included in the DMA setting information 222, and reads part of data of the user code 231 stored in the program area 23 of the memory 21 in the predetermined size from the reading start address. After that, the DMA 25 continues to read remaining data in the predetermined size from an address subsequent to the address of the data that is read the last time.

Further the DMA 25 transfers the user code 231 read from the program area 23 to the CRC circuit 26 (S24). Specifically, the DMA 25 outputs the user code 231, which is read from the memory 21 by the predetermined size at a time in order, to the CRC circuit 26 in order. Note that the DMA 25 outputs the transfer completion interrupt signal to the CPU 27 when the DMA 25 has finished transferring the user code 231.

After that, the CRC circuit 26 generates a CRC code from the transferred user code 231 (S25). Specifically, the CRC circuit 26 executes calculation by using the Cyclic Redundancy Check scheme for each area of the user code 231 transferred in the predetermined size from the DMA 25, and generates a CRC code.

Further the CPU 27 compares the CRC code generated with the reference CRC code (S26). Specifically, first, the CPU 27 receives the transfer completion interrupt signal from the DMA 25. Next, the CPU 27 reads the CRC code from the register 261. Further the CPU 27 reads the reference CRC code 221 from the memory 21. After that, the CPU 27 compares the CRC code read from the register 261 with the reference CRC code 221.

Note that since the processing of the step S23 to S25 is executed in the predetermined size in succession, the CRC circuit 26 executes CRC code generation processing on data that was already transferred during the data transfer processing by the DMA 25. However, the executing time of the CRC code generation processing is short. Therefore, the DMA 25 outputs the transfer completion interrupt signal to the CPU 27 as soon as the DMA 25 has finished the data transfer processing, and the DMA 25 has finished the last CRC code generation processing by the CRC circuit 26 while the CPU 27 receives the transfer completion interrupt signal. Therefore, the efficiency of processing of the CPU 27 is increased by reading a CRC code from the register 261 as soon as the CPU 27 receives the transfer completion interrupt signal.

After that, the CPU 27 determines whether or not an error occurs based on a result of the step S26 (S27). For example, the CPU 27 determines that an error has occurred, if the CRC code generated by the CRC circuit 26 and the reference CRC code 221 are different.

If the CPU 27 determines that an error occurs in the step S27, the CPU 27 outputs an error signal (S28). In this case, it indicates that the value of the user code 231 stored in the memory 21 is different from the original value of the user code 231 at the time when the reference CRC code 221 was generated. For example, it is possible that the program area 23 is broken by the deterioration of the memory 21. Alternately, it is possible that the reference CRC code 221 has been changed from the original value at the time when the reference CRC code 221 was generated due to the broken control information area 22. In any case, the CPU 27 detects an error in the memory 21. Therefore, afterward, the microcomputer 200 can stop processing without performing an operation of the user program.

If the CPU 27 determines that an error does not occur in the step S27, the CPU 27 can read the user program and start any given predetermined processing.

As described above, according to the second exemplary embodiment of the present invention, the microcomputer 200 automatically starts the error detection processing immediately after the power of the microcomputer 200 is turned on without requiring any intervention from a user. Further, the microcomputer 200 can completes the error detection processing during the startup routine performed between the turning-on of the power and the user program execution.

Further, according to the second exemplary embodiment of the present invention, by using the DMA 25 as the transfer circuit, the microcomputer 200 can perform the data transfer processing from the memory 21 to the CRC circuit 26 directly by hardware. Therefore, it is possible to speed up the data transfer processing compared with Japanese Unexamined Patent Application Publication No. 2001-344992. Therefore, the time required for the error detection processing of the data memory can be shortened.

Note that the demand from the customer for the reduction in time necessary between the turning-on of the power and the user program execution is growing every year. For example, it has been desired to carry out in about several dozen milliseconds. However, the method disclosed by Japanese Unexamined Patent Application Publication No. 2001-344992 requires about several seconds, because it performs the data transfer by software controlling. Moreover, in Japanese Unexamined Patent Application Publication No. 2001-344992, the execution of the software for the memory checking requires an intervention from a user. Therefore, the error detection processing cannot start automatically. Moreover, it takes a long time for the operation, and as a result, the overall error detection processing time is increased.

According to the second exemplary embodiment of the present invention, the DMA setting circuit 24, which is a purpose-built circuit for the DMA configuration, reads the DMA setting information 222 from the memory 21 and makes setting for the DMA 25 at the start-up of the microcomputer 200. Therefore, the microcomputer 200 can automatically start the data transfer for the error detection processing. Herewith, the error detection processing starts more quickly.

Moreover, by adding the DMA setting circuit 24, the microcomputer 200 starts the error detection processing without requiring any intervention from a user.

Note that the DMA of the second exemplary embodiment of the present invention can be easily realized by using an existing DMA embedded in the microcomputer with or without making modification.

### Third Exemplary Embodiment

A third exemplary embodiment of the present invention is a modified embodiment of the second embodiment. The time necessary for the error detection processing becomes further shortened by checking only part of the data to be checked in the third exemplary embodiment of the present invention. The configuration and the processing of the microcomputer 200 according to the third exemplary embodiment of the present invention is similar to those shown in FIGS. 3 and 4, and are not described in detail.

For example, there is a case where only part of data of the user code 231 stored in the memory 21 is actual data. In this case, the microcomputer 200 does not need to perform the memory checking for the entire user code 231 to perform the error detection processing on the memory 21.

The DMA setting information 222 according to the third exemplary embodiment of the present invention includes a range to be transferred specifying part of the user code 231. For example, the range to be transferred is composed of a start address and an upper limit for the number of times of the transfers performed by the DMA 25. In other words, the range to be transferred is an area specifying a part of the program area 23 in the memory 21. This is because, since the DMA 25 performs reading with a fixed width in order from the start address, it can specify the area to be read by the number of times of the transfers. That is, the start address and upper limit for the number of times of transfers are preferably determined so that the area, which is part of the user code 231 and on which the memory test is to be performed, is contained within a range obtained by multiplying the fixed width with which the DMA 25 performs transfers from the start address by an integer. Further, the upper limit for the number of times of transfers is set to this integer.

The reference CRC code 221 according to the third exemplary embodiment of the present invention is a CRC code for the area of the range to be transferred of the user code 231. The DMA 25 according to the third exemplary embodiment of the present invention transfers the user code 231 located in the range to be transferred included in the DMA setting information 222 from the memory 21 to the CRC circuit 26. That is, the DMA 25 according to the third exemplary embodiment of the present invention successively reads the user code 231 from the memory 21 in the predetermined size until the repeat count reaches the transfer upper limit included in the DMA setting information 222.

Therefore, a user can omit extra transfer operations, for example, the transfer of an area that is not used by the user. So, the time necessary for the error detection processing of the data memory can be shortened.

### Forth Exemplary Embodiment

A forth exemplary embodiment of the present invention is another embodiment in accordance with the first exemplary embodiment. The forth exemplary embodiment of the present invention is also a modified embodiment of the second embodiment. The time necessary for the data transfer processing is further shortened, and the error detection processing starts more quickly by processing the data transfers in parallel with at least two DMA in the forth exemplary embodiment of the present invention. Note that the following explanation is made with emphasis on the difference from the second embodiment.

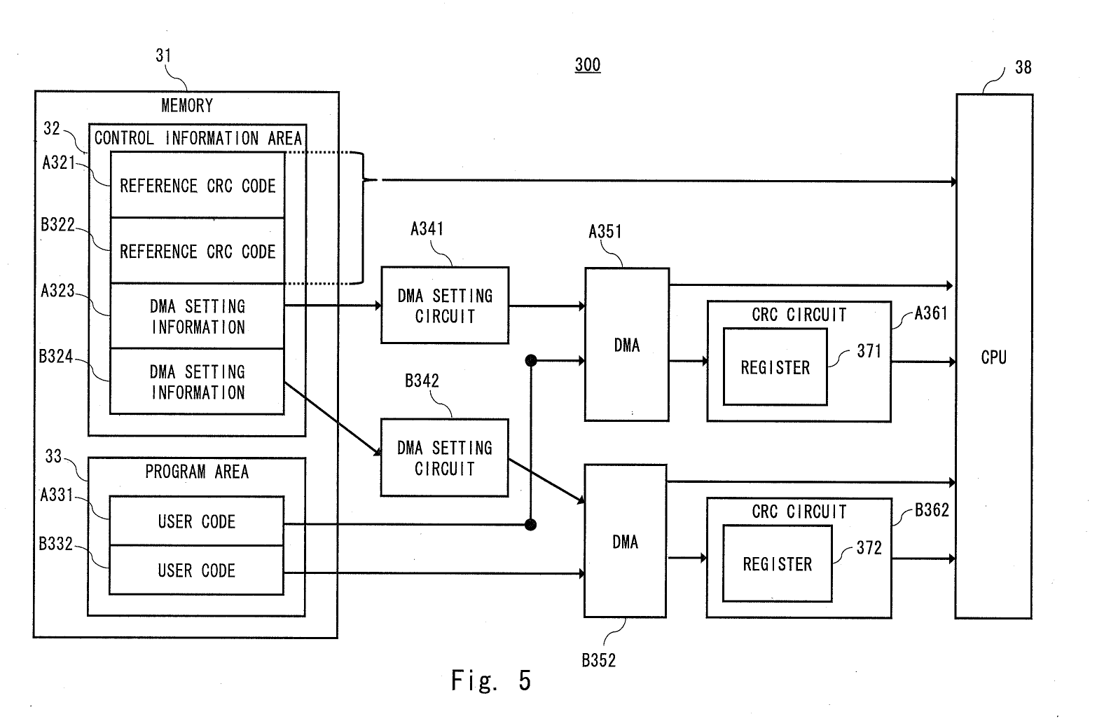

FIG. 5 is a block diagram showing a configuration of a microcomputer 300 according to a forth exemplary embodiment of the present invention. The microcomputer 300 includes a memory 31, a DMA setting circuit A341, a DMA setting circuit B342, a DMAA351, DMAB352, a CRC circuit A361, a CRC circuit B362, and a CPU 38. Note that the memory 31 is a storage device similar to the memory 21. Each of the DMA setting circuits A341 and B342 is an electronic circuit similar to the DMA setting circuit 24. Each of the DMAA351 and the DMAB352 is a DMA controller similar to the DMA 25. Each of the CRC circuits A361 and t B362 is an electronic circuit similar to the CRC circuit 26. The CPU 38 is a central processing unit similar to the CPU 27.

The memory 31 includes a control information area 32 and a program area 33. The control information area 32 is different from the control information area 22 in that a reference CRC code A321, a reference CRC code B322, a DMA setting information A323, and a DMA setting information B324 are stored in the control information 32. The program area 33 is different from the program area 23 in that a user code A331 and a user code B332 are stored in the program area 32. The user code A331, which is first data to be checked, is stored in a first area, which is a part of the program area 33. The user code B332, which is a second data to be checked, is stored in a second area, which is a part of the program area 33.

The reference CRC code A321 is code that is generated from the user code A331 in advance, by a Cyclic Redundancy Check scheme. That is, the reference CRC code A321 is first reference check code corresponding to the user code A331. The reference CRC code B322 is code generated from the user code B332 in advance, by a Cyclic Redundancy Check scheme. That is, the reference CRC code B322 is second reference check code corresponding to the user code B332. Further the DMA setting information A323 is first transfer setting information that is registered in advance in the memory 31 and specifies the first area in which the user code A331 is stored. In this example, the DMA setting information A323 indicates the memory 31 as the transfer source and the CRC circuit A361 as the transfer destination. The DMA setting information A323 indicates the start address of the user code A331 as the reading start address. The DMA setting information B324 is a second transfer setting information that is registered in advance in the memory 31, and specifies the second area in which the user code B332 is stored. In this example, the DMA setting information B324 is indicates the memory 31 as the transfer source and the CRC circuit B362 as the transfer destination. The DMA setting information B324 is indicates the start address of the user code B332 as the reading start address. The DMA setting circuit A341 reads the DMA setting information A323 from the memory 31 at the start-up of the microcomputer 300, and outputs a transfer instruction including the DMA setting information A323 to the DMAA351. The DMA setting circuit B342 reads the DMA setting information B324 from the memory 31 at the start-up of the microcomputer 300, and outputs a transfer instruction including the DMA setting information B324 to the DMAB352. Note that the DMA setting circuit A341 and the DMA setting circuit B342 may be the one and same DMA setting circuit. In this case, the one DMA setting circuit reads the DMA setting information A323 and the DMA setting information B324 from the memory 31 at the start-up of the microcomputer 300, and outputs a transfer instruction including the DMA setting information A323 DMA and a transfer instruction including the DMA setting information B324 to the DMAA351 and the DMAB352 respectively.

The DMAA351 outputs the user code A331 from the memory 31 to the CRC circuit A361 based on the DMA setting information A323. That is, the DMAA351 outputs the user code A331 from the memory 31, which is the transfer source, to the CRC circuit A361, which is the transfer destination, based on the DMA setting information A323 included in the transfer instruction from the DMA setting circuit A341. The DMAA351 outputs a transfer completion interrupt signal to the CPU 38 when the DMAA351 has finished transferring the user code A331 from the memory 31 to the CRC circuit A361. That is, the DMAA351 outputs a first check instruction to instruct the CPU 38 to check the first area after transferring the user code A331.

The DMAB352 outputs the user code B332 from the memory 31 to the CRC circuit B362, in parallel with the DMAA351, based on the DMA setting information B324DMA. That is, the DMAB352 outputs the user code B332 from the memory 31, which is the transfer source, to the CRC circuit B362, which is the transfer destination, based on the DMA setting information B324 included in the transfer instruction from the DMA setting circuit B342. The DMAB352 outputs a transfer completion interrupt signal to the CPU 38 when the DMAB352 has finished transferring the user code B332 from the memory 31 to the CRC circuit B362. That is, the DMAB352 outputs a second check instruction to instruct the CPU 38 to check the second area after transferring the user code B332. Note that the DMAA351 and the DMAB352 do not necessarily have to operate simultaneously, provided that they operate independently.

The CRC circuit A361 generates a first check code from the user code A331 transferred by the DMAA351, and stores it in the register 371 to store the CRC code. The CRC circuit B362 generates a second check code from the user code B332 transferred by the DMAB352, and stores it in the register 372 to store the CRC code. Note that the CRC circuit A361 can be regarded as a first check code generation unit, and the CRC circuit B362 can be regarded as a second check code generation unit.

The CPU 38 checks the user code A331 by using the first check code stored in the register 371 and the reference CRC code A321, when it received the transfer completion interrupt signal from the DMAA351. The CPU 38 checks the user code B332 by using the second check code stored in the register 372 and the reference CRC code B322, when it received the transfer completion interrupt signal from the DMAB352. The CPU 38 can be regarded as a check process unit that checks the memory 31. Note that the memory checking program may implement a logic corresponding to the CRC circuit A361 and the CRC circuit B362. In this case, processing including the CRC circuit A361 and the CRC circuit B362 is executed. Therefore, the CPU 38 checks the first area by using the user code A331 transferred from the DMAA351 and the reference CRC code A321, when it received the first check instruction. Further, the CPU 38 checks the second area by using the user code B332 transferred from the DMAB352 and the reference CRC code B322, when it received the second check instruction. The CPU 38 can check the memory 31 in this way.

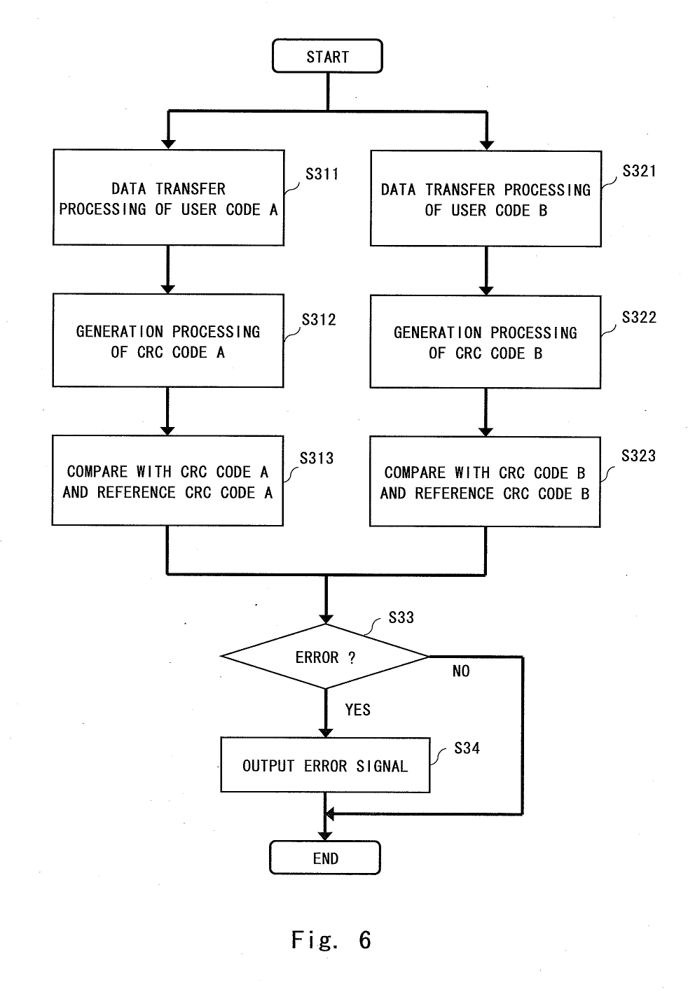

FIG. 6 is a flowchart showing processing of a memory checking method according to a forth exemplary embodiment of the present invention. First, the DMA setting circuit A341 performs the data transfer processing of the user code A331 (S311). That is, the DMA setting circuit A341 reads the DMA setting information A323 from the memory 31 at the time of the start of checking on the memory 31, and outputs the transfer instruction including the DMA setting information A323 to the DMAA351. Further, the DMAA351 transfers the user code A331 from the memory 31 to the CRC circuit A361 based on the DMA setting information A323. Specifically, since the transfer source including the DMA setting information A323 is the memory 31, the DMAA351 connects to the memory 31. In addition, the DMAA351 refers to the reading start address included in the DMA setting information A323, and reads part of data of the user code A331 stored in the program area 33 of the memory 31 in the predetermined size from the reading start address. After that, the DMAA351 continues to read remaining data in the predetermined size from an address subsequent to the address of the data that is read the last time. Further the DMAA351 outputs the user code A331, which is read from the memory 31 by the predetermined size, at a time in order, to the CRC circuit A361 in order. Note that the DMAA351 outputs the transfer completion interrupt signal to the CPU 38, when the DMAA351 has finished transferring the user code A331.

Next, CRC circuit A361 performs the generation processing of a CRC code A (S312). That is, the CRC circuit A361 generates the CRC code A as the first check code from the user code A331, when the user code A331 is transferred by the step S311. Then, CRC circuit A361 stores the generated CRC code A in the register 371.

Further the CPU 38 compares the CRC code A generated with the reference CRC code A321 (S313). Specifically, first, the CPU 38 receives the transfer completion interrupt signal from the DMAA351. Next, the CPU 38 reads the CRC code A from the register 371. Further the CPU 38 reads the reference CRC code A321 from the memory 31. After that, the CPU 38 compares the CRC code A read from the register 371 with the reference CRC code A321.

Further, processes from a step S321 to S323 are different from the processes from a step S311 to S313 in that the DMA setting circuit A341, the DMAA351, and the CRC circuit A361 are replaced by the DMA setting circuit B342, the DMAB352, and the CRC circuit B362. However, operations of the processes from a step S321 to S323 are similar to the operations described above, and are not described in detail.

After that, the CPU 38 determines whether or not an error occurs in at least one of the result of the step S313 and the result of the step S323 (S33). If the CPU 38 determines that an error has occurred in at least one of the step S313 and S323, the CPU 38 outputs an error signal (S34). For example, the CPU 38 may determine after both the process in the step S313 and the process in the step S323 have finished. Alternatively the CPU 38 may determine whenever either the process in the step S313 or the process by the step S323 has finished. That is, the CPU 38 checks the first area in which the user code A331 is stored by using the reference CRC code A321, when the user code A331 is transferred by the DMAA351. Further the CPU 38 checks the second area in which the user code B332 is stored by using the reference CRC code B322, when the user code B332 is transferred by the DMAB352. In this way, the CPU 38 checks the memory 31.

As described above, according to the forth exemplary embodiment of the present invention, the microcomputer 300 can perform the data transfer processing in parallel, and start the error detection processing more quickly than Japanese Unexamined Patent Application Publication No. 2001-344992.

### Other Exemplary Embodiments

Note that the microcomputer 300 may include other transfer circuits different from the DMA 25, so that a plurality of the data transfer processing may be executing in parallel by the other transfer circuits. In this case, the DMA setting information 222 includes first specification information that specifies a first area of the program area 23 as a range to be transferred and second specification information that specifies a second area of the program area 23 as a range to be transferred. Further the transfer circuit executes a first transfer processing and a second transfer processing in parallel. In the first transfer processing, a first data to be checked in the first area, which is part of the user code 231, is read from the memory 21 and transferred to the CRC circuit 26 based on the first specification information. In the second transfer processing, a second data to be checked in the second area, which is part of the user code 231, is read from the memory 21 and transferred to the CRC circuit 26 based on the second specification information. Further the check circuit checks the memory 21 by using the first data to be checked that is transferred by the first transfer processing, the second data to be checked that is transferred by the second transfer processing, and the reference CRC code 221.

Moreover, the check circuit may include a first check code generation unit, a second check code generation unit, and a check process unit. In this case, the first check code generation unit generates first check code from the first data to be checked that is transferred by the first transfer processing. The second check code generation unit generates second check code from the second data to be checked that is transferred by the second transfer processing. The check process unit checks the first area by using the first check code and a first reference check code corresponding to the first data to be checked, and checks the second area by using the second check code and the second reference check code corresponding to the second data to be checked.

Alternatively, the transfer circuit may execute a first transfer processing and a second transfer processing in parallel. In the first transfer processing, a first data to be checked in the first area, which is included in the program area 23, is read from the memory 21 and transferred to the check circuit based on the first specification information. In the second transfer processing, a second data to be checked in the second area, which is included in the program area 23, is read from the memory 21 and transferred to the check circuit based on the second specification information. Further the check circuit may check the memory 21 by using the first data to be checked that is transferred by the first transfer processing, the second data to be checked that is transferred by the second transfer processing, and the reference CRC code 221.

The present invention is not limited to the above-described exemplary embodiments, and various modifications can be made as appropriate to the exemplary embodiments without departing from the spirit and scope of the present invention.

The first, second, third and four exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A memory checking system comprising:
a memory that stores a data to be checked;
a check circuit that checks the memory by using the data to be checked and a reference check code of the data to be checked; and
a transfer circuit that transfers the data to be checked from the memory to the check circuit based on a transfer setting information of the data to be checked, the transfer setting information being registered in advance.

2. The memory checking system according to claim 1, further comprising a transfer instruction circuit that outputs a transfer instruction including the transfer setting information to the transfer circuit, wherein
the transfer circuit transfers the data to be checked from the memory to the check circuit based on the transfer setting information included in the transfer instruction from the transfer instruction circuit.

3. The memory checking system according to claim 2, wherein
the memory further stores transfer setting information of the data to be checked, and
the transfer instruction circuit reads the transfer setting information from the memory at start-up of the memory checking system.

4. The memory checking system according to claim 1, wherein
the memory further stores reference check code of the data to be checked, and
the check circuit reads the reference check code of the data to be checked from the memory to check the memory.

5. The memory checking system according to claim 1, wherein
the transfer setting information includes a range to be transferred specifying a part of the memory, and
the transfer circuit transfers the data to be checked from the memory to the check circuit, the data to be checked being located in the range to be transferred included in the transfer setting information.

6. The memory checking system according to claim 1, wherein
the transfer setting information includes first specification information that specifies a first area of the memory as a range to be transferred and second specification information that specifies a second area of the memory as a range to be transferred,
the transfer circuit executes a first transfer processing and a second transfer processing in parallel, a first data to be checked in the first area being read from the memory and transferred to the check circuit based on the first specification information in the first transfer processing, and a second data to be checked in the second area being read from the memory and transferred to the check circuit based on the second specification information in the second transfer processing, and
the check circuit checks the memory by using the first data to be checked that is transferred by the first transfer processing, the second data to be checked that is transferred by the second transfer processing, and the reference check code.

7. The memory checking system according to claim 6, wherein
the reference check code includes first reference check code corresponding to the first data to be checked and second reference check code corresponding to the second data to be checked,
the check circuit including:
a first check code generation unit that generates first check code from the first data to be checked,
a second check code generation unit that generates second check code from the second data to be checked, and
a check process unit that checks the first area by using the first check code and the first reference check code, and checks the second area by using the second check code and the second reference check code.

8. The memory checking system according to claim 1, wherein the transfer circuit is a DMA (Direct Memory Access) controller.

9. A memory checking method for checking a memory storing data to be checked by using a transfer circuit and a check circuit, the memory checking method comprising:
reading, by the transfer circuit, the data to be checked from the memory based on a transfer setting information registered in advance in the memory,
transferring, by the transfer circuit, the data to be checked read from the memory to the check circuit,
checking, by the check circuit, the memory by using the data to be checked and a reference check code of the data to be checked.

10. The memory checking method according to claim 9, further comprising outputting, by a transfer instruction circuit, a transfer instruction including the transfer setting information to the transfer circuit, wherein
in the reading, the data to be checked is read, by the transfer circuit, from the memory based on a transfer setting information included in the transfer instruction.

11. The memory checking method according to claim 10, wherein
the memory further stores transfer setting information of the data to be checked, and
in the outputting, the transfer setting information is read, by the transfer instruction circuit, from the memory at the time of start of checking on the memory.

12. The memory checking method according to claim 9, wherein
the memory further stores reference check code of the data to be checked,
wherein in the checking,
the reference check code of the data to be checked is read, by the check circuit, from the memory to check the memory.

13. The memory checking method according to claim 9, wherein
the transfer setting information includes a range to be transferred specifying a part of the memory,
wherein in the reading,
the data to be checked in the range to be transferred included in the transfer setting information is read, by the transfer circuit, from the memory.

14. The memory checking method according to claim 9, wherein
the transfer setting information includes first specification information that specifies a first area of the memory as a range to be transferred and second specification information that specifies a second area of the memory as a range to be transferred,
wherein in the reading,
it is executed, by the transfer circuit, a first transfer processing and a second transfer processing in parallel, a first data to be checked in the first area being read from the memory and transferred to the check circuit based on the first specification information in the first transfer processing, and a second data to be checked in the second area being read from the memory and transferred to the check circuit based on the second specification information in the second transfer processing, and
in the checking,
the memory is checked, by the check circuit, by using the first data to be checked that is transferred by the first transfer processing, the second data to be checked that is transferred by the second transfer processing, and the reference check code.

15. The memory checking method according to claim 14, wherein
the reference check code includes first reference check code corresponding to the first data to be checked and second reference check code corresponding to the second data to be checked,
wherein in the checking, by the check circuit,
first check code is generated from the first data to be checked,
second check code is generated from the second data to be checked,
the first area is checked with the first check code and the first reference check code, and
the second area is checked with the second check code and the second reference check code.

16. A memory checking system comprising:
a memory that stores a first data to be checked in a first area and a second data to be checked in a second area;
a check circuit that checks the memory by using the first data to be checked, the second data to be checked, a first reference check code corresponding to the first data to be checked, and a second reference check code corresponding to the second data to be checked;
a first transfer circuit that transfers the first data to be checked from the memory to the check circuit based on a first transfer setting information registered in advance in the memory specifying the first area;
a second transfer circuit that transfers the second data to be checked from the memory to the check circuit based on a second transfer setting information registered in advance in the memory in parallel with the first transfer circuit, the second transfer setting information specifying the second area.

17. The memory checking system according to claim 16, wherein
the first transfer circuit outputs a first check instruction to instruct the check circuit to check the first area after transferring the first data to be checked,
the second transfer circuit outputs a second check instruction to instruct the check circuit to check the second area after transferring the second data to be checked, and
the check circuit checks the memory by checking the first area by using the first data to be checked that is transferred from the first transfer circuit and the first reference check code when the check circuit received the first check instruction, and by checking the second area by using the second data to be checked that is transferred from the second transfer circuit and the second reference check code when the check circuit received the second check instruction.

18. The memory checking system according to claim 16, wherein
the memory further stores the first transfer setting information and the second transfer setting information,
the memory checking system further comprising a transfer instruction circuit that reads the first transfer setting information and the second transfer setting information from the memory at start-up of the memory checking system, outputs a transfer instruction including the first transfer setting information to the first transfer circuit, and issues a transfer instruction including the second transfer setting information to the second transfer circuit,
the first transfer circuit transfers the first data to be checked from the memory to the check circuit based on the first transfer setting information included in the transfer instruction from the transfer instruction circuit, and
the second transfer circuit transfers the second data to be checked from the memory to the check circuit based on the second transfer setting information included in the transfer instruction from the transfer instruction circuit.

19. The memory checking system according to claim 16, wherein
the check circuit including:
a first check code generation unit that generates a first check code from the first data to be checked,
a second check code generation unit that generates a second check code from the second data to be checked, and
a check process unit that checks the first area by using the first check code and the first reference check code, and checks the second area by using the second check code and the second reference check code.

20. The memory checking system according to claim 16, wherein the transfer circuit is a DMA (Direct Memory Access) controller.
